(19) United States
(12) Patent Application Publication
(10) Pub. No.: US 2017/0336677 A1
(43) Pub. Date: Nov. 23, 2017

(54) LIGHTING DEVICE AND DISPLAY DEVICE

(71) Applicant: Sharp Kabushiki Kaisha, Osaka (JP)

(72) Inventor: YUHSAKU AJICHI, Osaka (JP)

(73) Assignee: Sharp Kabushiki Kaisha, Osaka (JP)

(21) Appl. No.: 15/522,128

(22) PCT Filed: Oct. 30, 2015
(86) PCT No.: PCT/JP2015/080810

§ 371 Date: Apr. 26, 2017

(30) Foreign Application Priority Data
Nov. 6, 2014 (JP) 2014-226421

(51) Int. Cl. G02F 1/1335; H01L 33/56; H01L 33/50; H01L 25/075; H01L 33/62; H01L 33/60; H01L 33/48

(52) U.S. Cl. CPC G02F 1/133609; G02F 1/133603; H01L 33/60; H01L 33/56; H01L 33/486; H01L 25/0753; G02F 2001/133613; H01L 33/62; H01L 33/502

(57) ABSTRACT

An increase in cost is prevented and, at the same time, color irregularities in a lighting device and a display device including an arrangement of LEDs each including a plurality of LED chips mounted therein is prevented. An LED (10A2) is positioned so that its M-LED chip (13M2) is placed at a short distance from that one of G-LED chips (13G1) located adjacent to the M-LED chip (13M2) in both row-wise directions which is mounted in an LED (10A1) belonging to the same LED group (20A) as the LED (10A2).

### TECHNICAL FIELD

The present invention relates to a lighting device and a display device.

### BACKGROUND ART

A liquid crystal display includes a liquid crystal panel and a backlight that illuminates the liquid crystal panel from behind. The liquid crystal panel has a shutter function of causing light from the backlight to be transmitted through or blocked by given pixels to form an image.

Conventionally, most backlights have included fluorescent lamps such as CCFLs (cold cathode fluorescent lamps) as their light sources. However, recently, most backlights have included LEDs (light-emitting diodes) as their light sources with improved light emission efficiency.

FIG. 9 is a cross-sectional view of a conventional backlight as taken along a direction parallel to a flat surface. As shown in FIG. 9, the backlight 203 includes a casing 204 and light sources 210 regularly arranged in rows (in a horizontal direction as seen from the front of the surface of paper) and columns (in a vertical direction as seen from the front of the surface of paper) in a matrix on a bottom surface of the casing 204. The light sources 210 are LEDs.

Conventionally, the backlight 203 has included, as each of its light sources 210, an LED that gives off white light through a phosphor molded on a blue LED chip that emits blue light. Recently, for further improvement in color rendering properties of liquid crystal displays, each of the light sources 210 has sometimes been configured to emit white light through a plurality of LEDs configured to emit red, green, and blue lights, respectively, and separately mounted on a substrate.

FIG. 10 illustrates diagrams each showing one or more LEDs constituting a light source 210: (a) a diagram showing a combination of a red LED 213R, a green LED 213G, and a blue LED 213B; (b) a diagram showing a combination of two red LEDs 213R, two green LEDs 213G, and a blue LED 213B; and (c) a diagram showing a white LED 213W including a blue LED chip and a phosphor molded on the blue LED chip.

It should be noted that the LEDs (the red LEDs 213R, the green LEDs 213G, the blue LEDs 213B, and the white LED 213W) shown in FIG. 10 are each separately packaged. Further, another possible example of a combination of LEDs for giving off white light is a combination of a green LED and a magenta LED.

Further, in recent years, LEDs each including a plurality of LED chips mounted into one package have been used to reduce costs.

PTL 1 discloses a copier whose document reader includes LEDs. The LEDs used in the copier are unidirectionally arranged in a line on an elongated LED-mounting board. Each of the LEDs is configured as one package including three blue LED chips located at the vertices of a triangle and a phosphor that emits a yellow fluorescence in response to radiated light from the three blue LED chips.

Moreover, the LEDs arranged in a line on the LED-mounting board are placed at regular intervals so that the three blue LED chips of a first LED are opposite in arrangement to the three blue LED chips of a second LED located adjacent to the first LED.

According to PTL 1, this allows blue light and yellow light to be mixed together to make color irregularities inconspicuous.

### CITATION LIST

### Patent Literature

PTL 1: Japanese Unexamined Patent Application Publication No. 2012-114760 (published on Jun. 14, 2012)

### SUMMARY OF INVENTION

### Technical Problem

FIG. 11 is a cross-sectional view of a backlight as taken along a direction parallel to a flat surface, the backlight including an arrangement of LEDs oriented in the same direction, the LEDs each including a magenta LED chip (hereinafter referred to as “M-LED chip”) and a green LED chip (hereinafter referred to as “G-LED chip”) mounted into one package.

As shown in FIG. 11, the backlight 203A includes a substrate 204 and LEDs 210A arranged at regular intervals in rows (in the horizontal direction as seen from the front of the surface of paper) and columns (in the vertical direction as seen from the front of the surface of paper) on the substrate 204. Each of the LEDs 210A includes M-LED and G-LED chips 213M and 213G mounted into one package. Moreover each of the LEDs 210A is positioned in the plane of the substrate 204 with the M-LED and G-LED chips 213M and 213G oriented in a given direction.

However, in the case of a liquid crystal display including such a backlight 203A, there are too many LED chips of the same colors arranged at the edges of the screen, with the result that color irregularities appear depending on the orientation in which the LEDs 210A are arranged.

That is, the M-LED chips 213M are arranged in a row-wise line along a first one of two opposed edges of the substrate 204, and the G-LED chips 213G are arranged in a row-wise line along a second one of the two opposed edges. This causes a region 203AM, which is located near the first edge along which the M-LED chips 213M are arranged in a line, to turn magenta, while causing a region 203AG, which is located near the second edge along which the G-LED chips 213G are arranged in a line, to turn green.

FIG. 12 is a cross-sectional view of a backlight as taken along a direction parallel to a flat surface, the backlight including such an arrangement of LEDs that row-wise adjacent LEDs are opposite in M-LED chip and G-LED chip orientation to each other.

As shown in FIG. 12, the backlight 203B includes a substrate 204. LEDs 210B1 each including G-LED and M-LED chips 231G1 and 231M1 located in higher and lower positions, respectively, than each other as seen from the front of the surface of paper, and LEDs 210B2 each including M-LED and G-LED chips 213M2 and 213G2 located in higher and lower positions, respectively, than each other as seen from the front of the surface of paper. The LEDs 210B1 and the LEDs 210B2 are placed at regular intervals on the substrate 204 in such a way as to be alternately lined up in rows. The LEDs 210B1 and the LEDs 210B2 are placed at regular intervals in such a way as to be separately lined up in columns.

However, the intervals at which the LEDs 210B1 and the LEDs 210B2 are arranged in rows are so wide that color irregularities appear in the form of alternate colors of green and yellow near the two edges of the substrate 204. That is, in the vicinity of the two opposed edges of the substrate 204, regions 203BG near which a G-LED chip 213G1 or a G-LED chip 213G2 is located turn green, and regions 203BM near which an M-LED chip 213M1 or an M-LED chip 213M2 is located turn magenta.

Narrowing the intervals at which the LEDs 210B1 and the LEDs 210B2 are arranged in rows allows green and magenta to be mixed together to be viewed as white, but requires a larger number of LEDs, resulting in an increase in manufacturing cost.

The LEDs described in PTL 1 do not need to be two-dimensionally arrayed like LEDs provided in a backlight for use in a display device but need only be arranged in a line, as the LEDs described in PTL 1 are used in the copier to read a document. For this reason, the number of LEDs used is small, and even if the intervals at which the LEDs are placed are narrowed for improving the color irregularities, there is no large increase in the number of LEDs and the resulting increased cost is not as remarkable as in the case of a backlight for use in a display device.

The present invention has been made to solve the foregoing problems, and it is an object of the present invention to prevent an increase in cost and, at the same time, prevent color irregularities in a lighting device and a display device including an arrangement of LEDs each including a plurality of LED chips mounted therein.

### Solution to Problem

In order to solve the foregoing problems, a lighting device according to an aspect of the present invention includes a plurality of LED groups arranged in rows and columns, the plurality of LED groups each including first and second LEDs, wherein each of the first and second LEDs includes first and second LED chips that emit different colors of light that become white by being mixed together, the first and second LEDs are arranged so that their respective first and second LED chips are located adjacent to each other in a row-wise direction, and the second LED of a first one of the LED groups is positioned so that a distance between the second LED chip of the second LED and the first LED chip of the first LED of the first LED group is shorter than a distance between the second LED chip of the second LED and the first LED chip of the first LED of a second LED group located adjacent to the first LED group in the row-wise direction.

### Advantageous Effects of Invention

An aspect of the present invention brings about an effect of preventing an increase in cost and, at the same time, preventing color irregularities in a lighting device including an arrangement of LEDs each including a plurality of LED chips mounted therein.

### BRIEF DESCRIPTION OF DRAWINGS

FIG. 1 is a cross-sectional view of a backlight according to Embodiment 1 of the present invention as taken along a direction parallel to a flat surface.

FIG. 2 illustrates diagrams showing a configuration of a liquid crystal display according to Embodiment 1 of the present invention.

FIG. 3 is a perspective view showing a configuration of an LED of the backlight according to Embodiment 1 of the present invention.

FIG. 4 illustrates a cross-sectional view (a) of a first trial-produced backlight as taken along a direction parallel to a flat surface and a cross-sectional view (b) of a second trial-produced backlight as taken along a direction parallel to a flat surface.

FIG. 5 illustrates a diagram (a) showing a result of measurement of a chromaticity y in the first trial-produced backlight and a diagram (b) showing a result of measurement of a chromaticity y in the second trial-produced backlight.

FIG. 6 is a cross-sectional view of a backlight according to Embodiment 2 of the present invention as taken along a direction parallel to a flat surface.

FIG. 7 is a cross-sectional view of a backlight according to Embodiment 3 of the present invention as taken along a direction parallel to a flat surface.

FIG. 8 is a cross-sectional view of a backlight according to Embodiment 4 of the present invention as taken along a direction parallel to a flat surface.

FIG. 9 is a cross-sectional view of a conventional backlight as taken along a direction parallel to a flat surface.

FIG. 10 illustrates diagrams showing a plurality of LEDs constituting light sources of the conventional backlight.

FIG. 11 is a cross-sectional view of a backlight as taken along a direction parallel to a flat surface, the backlight including an arrangement of LEDs oriented in the same direction, the LEDs each including M-LED and G-LED chips mounted into one package.

FIG. 12 is a cross-sectional view of a backlight as taken along a direction parallel to a flat surface, the backlight including such an arrangement of LEDs that M-LED chips and G-LED chips are opposite in orientation to each other.

### DESCRIPTION OF EMBODIMENTS

### Embodiment 1

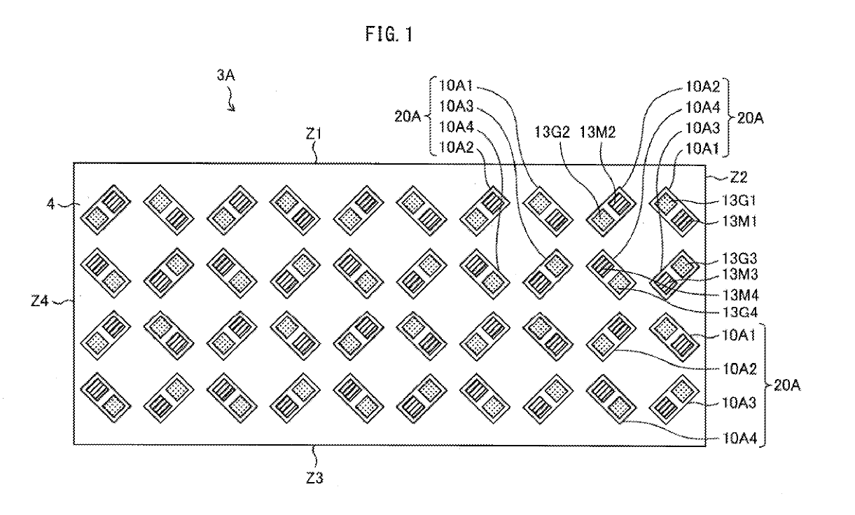

Embodiment 1 of the present invention is described in detail below with reference to FIGS. 1 to 5.

(Structures of Liquid Crystal Display and LED)

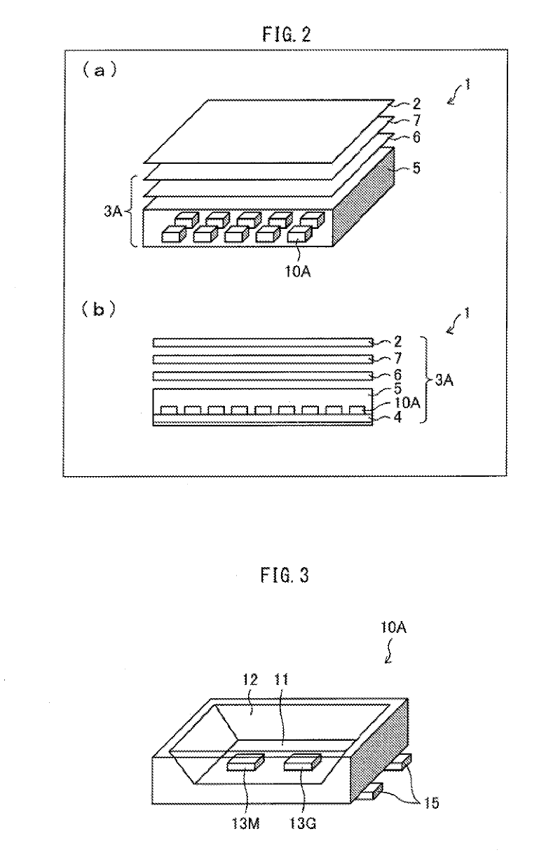

First, structures of a liquid crystal display according to the present embodiment and a structure of an LED of the liquid crystal display are described with reference to FIGS. 2 and 3. FIG. 2 illustrates diagrams showing a configuration of the liquid crystal display: (a) an exploded perspective view; and (b) a cross-sectional view of the liquid crystal display shown in (a) as taken along a direction parallel to a side surface.

As shown in FIG. 2, the liquid crystal display (display device) 1 includes a liquid crystal panel 2 and a backlight (lighting device) 3A provided behind the liquid crystal panel 2. The backlight 3A illuminates the liquid crystal panel 2 from behind. The liquid crystal panel 2 has a shutter function of causing light from the backlight 3A to be transmitted through or blocked by given pixels. This allows the liquid crystal display 1 to display an image.

The backlight 3A includes a substrate 4, a plurality of LEDs 10A mounted on the substrate 4, a casing 5 that houses the substrate 4 and the LEDs 10A a diffusing plate 6 that diffuses and uniforms light from the LEDs 10A, a lens sheet 7 for increasing frontward luminance by concentrating the light diffused by the diffusing plate 6, and a polarizing reflective sheet (not illustrated) for, by selectively reflecting or transmitting polarized light exiting from the lens sheet 7, allowing the light to efficiently enter the liquid crystal panel 2. The diffusing plate 6, the lens sheet 7, and the polarizing reflective sheet are stacked in this order in the direction of emission of light from the LEDs 10A. It should be noted that, depending on the product in which the backlight 3A is used, the diffusing plate 6, the lens sheet 7, and the polarizing reflective sheet may be omitted or another optical member may be provided. The backlight 3A is a so-called direct backlight with the LEDs 10A arranged in a matrix.

FIG. 3 is a perspective view showing a configuration of each of the LEDs 10A. The LED 10A is an LED including a plurality of LED chips configured to emit different colors of light that are complementary to each other and mounted into one package.

The LED 10A includes a G-LED chip (green LED chip) 13G that emits green light, an M-LED chip (magenta LED chip) 13M that emits magenta light, a substrate 11 on which the G-LED chip 13G and the M-LED chip 13M are mounted, a package section 12 in which a cavity is formed as a recess, and electrodes 15 for mounting the LED 10A onto the substrate 4 (see FIG. 2). The G-LED chip 13G and the M-LED chip 13M are lined up in a longitudinal direction of the LED 10A.

The M-LED chip 13M includes, for example, a blue LED chip (B-LED chip) that emits blue light and a resin that seals the B-LED chip, and the resin contains a phosphor that emits red light in response to blue light from the B-LED chip.

The package section 12 has a cavity formed as a recess surrounded by a height surrounding the substrate 11, the G-LED chip 13G, and the M-LED chip 13M. The G-LED chip 13G and the M-LED chip 13M are mounted on a surface of the substrate 11 so as to be in the recess of the package section 12. A reflecting member for reflecting lights from the G-LED chip 13G and the M-LED chip 13M may be provided on the interior walls of the recess of the package section 12. The package section 12 has its recess filled with a transparent resin material so that the G-LED chip 13G and the M-LED chip 13M are sealed.

The electrodes 15 are connected to the substrate 11 and exposed to the outside of the package section 12. The LED 10A is mounted onto the substrate 4 (see FIG. 2), for example, by soldering the electrodes 15. This enables the G-LED chip 13G and the M-LED chip 13M to be electrically connected to the substrate 4.

The LED 10A emits white light into the outside through a mixture of the complementary colors of green light emitted from the G-LED chip 13G and magenta light emitted from the M-LED chip 13M. Since the LED 10A has its G-LED and M-LED chips 13G and 13M mounted into one package, the cost of manufacturing the backlight can be made lower than in a case where, for example, an LED including only a G-LED chip 13G mounted therein and an LED including only an M-LED chip 13M mounted therein are separately mounted on the substrate 4 (see FIG. 2).

(Structure of Backlight)

Next, a structure of the backlight according to the present embodiment is described with reference to FIG. 1. FIG. 1 is a cross-sectional view of the backlight 3A according to Embodiment 1 as taken along a direction parallel to a flat surface.

The backlight 3A includes such an arrangement of LEDs that two LED chips of complementary colors are placed at a short distance from each other in the center of the screen of the liquid crystal display including the backlight 3A and two LED chips of complementary colors are also placed at a short distance from each other at an edge of the screen. The liquid crystal display including the backlight 3A does not suffer from the appearance of color irregularities in any area on the screen. The following specifically describes the structure of the backlight 3A including such an arrangement of LEDs.

As shown in FIG. 1, the backlight 3A includes a plurality of LED groups 20A mounted on the substrate 4 and arranged in a matrix by being arranged in rows (in the horizontal direction as seen from the front of the surface of paper) and columns (in the vertical direction as seen from the front of the surface of paper) that are orthogonal to the rows.

The LED groups 20A are arranged at regular intervals both in rows and columns. Although FIG. 1 shows an example in which the LED groups 20A are arranged in two rows and five columns, the number of LED groups 20A is not limited to this example but may be changed as appropriate according to the size of the backlight 3A and the product in which the backlight 3A is used.

Each of the LED groups 20A includes a plurality of LEDs 10A1, 10A2, 10A3, and 10A4 each of which is identical in configuration to the LED 10A (see FIG. 3).

The LED (first LED) 10A1 includes a G-LED chip (first LED chip) 13G1 and an M-LED chip (second LED chip) 13M1. The LED (second LED) 10A2 includes a G-LED chip (first LED chip) 13G2 and an M-LED chip (second LED chip) 13M2. The LED (third LED) 10A3 includes a G-LED chip (first LED chip) 13G3 and an M-LED chip (second LED chip) 13M3. The LED (fourth LED) 10A4 includes a G-LED chip (first LED chip) 13G4 and an M-LED chip (second LED chip) 13M4. The G-LED chips 13G1, 13G2, 13G3, and 13G4 are LED chips that emit green light and are identical in configuration to the G-LED chip 13G (see FIG. 3). The M-LED chips 13M1, 13M2, 13M3, and 13M4 are LED chips that emit magenta light and are identical in configuration to the M-LED chip 13M (see FIG. 3).

The LEDs 10A1, 10A2, 10A3, and 10A4 are arranged so that LED chips that emit complementary colors of light are located adjacent to each other in row-wise and column-wise directions.

The LED 10A2 is located adjacent to the LED 10A1 in the row-wise direction, and the LED 10A3 is located adjacent to the LED 10A1 in the column-wise direction. The LED 10A4 is located adjacent to the LED 10A3 in the row-wise direction. That is, the LED 10A4 is located adjacent to the LED 10A2 in the column-wise direction.

The LED 10A2 is positioned so that the M-LED chip 13M2 is located adjacent to the G-LED chip 13G1 of the LED 10A1 in the row-wise direction and the G-LED chip 13G2 is located adjacent to the M-LED chip M1 of the LED 10A1 in the row-wise direction. The LED 10A3 is positioned so that the G-LED chip 13G3 is located adjacent to the M-LED chip 13M1 of the LED 10A1 in the column-wise direction and the M-LED chip 13M3 is located adjacent to the G-LED chip G1 of the LED 10A1 in the column-wise direction. The LED 10A4 is positioned so that the G-LED chip 13G4 is located adjacent to the M-LED chip 13M3 of the LED 10A3 in the row-wise direction and the M-LED chip 13M4 is located adjacent to the G-LED chip 13G3 of the LED 10A3 in the row-wise direction.

The LED 10A1 is positioned so that the direction (longitudinal direction) in which the G-LED chip 13G1 and the M-LED chip 13M1 are lined up is tilted at approximately −45 degrees with respect to the direction (row-wise direction) in which the LED 10A1 and the LED 10A2 are lined up. The LED 10A2 is positioned so that the direction (longitudinal direction) in which the M-LED chip 13M2 and the G-LED chip 13G2 are lined up is tilted at approximately 45 degrees with respect to the direction (row-wise direction) in which the LED 10A1 and the LED 10A2 are lined up.

The LED 10A3 is positioned so that the direction (longitudinal direction) in which the G-LED chip 13G3 and the M-LED chip 13M3 are lined up is tilted at approximately 45 degrees with respect to the direction (row-wise direction) in which the LED 10A3 and the LED 10A4 are lined up. The LED 10A4 is positioned so that the direction (longitudinal direction) in which the M-LED chip 13M4 and the G-LED chip 13G4 are lined up is tilted at approximately −45 degrees with respect to the direction (row-wise direction) in which the LED 10A3 and the LED 10A4 are lined up.

The LEDs 10A1, 10A2, 10A3, and 10A4 may also be expressed as being arranged in rotation symmetry with respect to the central axis.

On the substrate 4 of the backlight 3A, the plurality of LED groups 20A each including such an arrangement of LEDs 10A1, 10A2, 10A3, 10A4 are arranged in rows and columns. The backlight 3A includes an arrangement of LEDs in an even number of columns and an even number of rows.

From the column-wise perspective, in the rightmost column as seen from the front of the surface of paper, an LED 10A1 tilted at approximately −45 degrees, an LED 10A3 tilted at approximately 45 degrees, an LED 10A1 tilted at approximately −45 degrees, and an LED 10A3 tilted at approximately 45 degrees are arranged in this order from top to bottom as seen from the front of the surface of paper. LEDs 10A1 and 10A3 are similarly arranged in an odd-numbered column as counted from the right as seen from the front of the surface of paper. In the second rightmost column as seen from the front of the surface of paper, an LED 10A2 tilted at approximately 45 degrees, an LED 10A4 tilted at approximately −45 degrees, an LED 10A2 tilted at approximately 45 degrees, and an LED 10A4 tilted at approximately −45 degrees are arranged in this order from top to bottom as seen from the front of the surface of paper. LEDs 10A2 and 10A4 are similarly arranged in an even-numbered column as counted from the right as seen from the front of the surface of paper. Thus, the backlight 3A includes an arrangement of LEDs placed opposite in angle to each other every 1 column.

From the row-wise perspective, in the uppermost row as seen from the front of the surface of paper, an LED 10A1 tilted at approximately −45 degrees, an LED 10A2 tilted at approximately 45 degrees, an LED 10A1 tilted at approximately −45 degrees, an LED 10A2 tilted at approximately −45 degrees, . . . , an LED 10A1 tilted at approximately −45 degrees, and an LED 10A2 tilted at approximately 45 degrees are arranged in this order in a direction from right to left. LEDs 10A1 and 10A2 are similarly arranged in an odd-numbered row as counted from the top as seen from the front of the surface of paper. In the second uppermost row as seen from the front of the surface of paper, an LED 10A3 tilted at approximately 45 degrees, an LED 10A4 tilted at approximately −45 degrees, an LED 10A3 tilted at approximately 45 degrees, an LED 10A4 tilted at approximately 45 degrees . . . an LED 10A3 tilted at approximately 45 degrees, and an LED 10A4 tilted at approximately −45 degrees are arranged in this order in a direction from right to left. LEDs 10A3 and 10A4 are similarly arranged in an even-numbered row as counted from the top as seen from the front of the surface of paper. Thus, the backlight 3A includes an arrangement of LEDs placed opposite in angle to each other every 1 row.

Thus, the backlight 3A includes such an arrangement of LEDs 10A1 and 10A2 that the G-LED chips 13G1 mounted in the LEDs 10A and the M-LED chips 13M2 mounted in the LEDs 10A2 are located adjacent to each other in the row-wise direction. Further, the M-LED chips 13M1 and the G-LED chips 13G2 are located adjacent to each other in the row-wise direction.

Attention is here focused on a first one (e.g. the upper right LED group 20A as seen from the front of the surface of paper) of the LED groups 20A arranged in rows and columns in the backlight 3A.

The M-LED chip 13M2 mounted in the LED 10A2 of the first LED group 20A and the G-LED chip 13G1 mounted in the LED 10A1 of the same first LED group 20A are placed at a distance that is shorter than the distance between the M-LED chip 13M2 mounted in the LED 10A2 of the first LED group 20A and the G-LED chip 13G1 of the LED 10A1 of a second LED group 20A (e.g. the LED group 20A located on the immediate left side of the upper right LED group 20A as seen from the front of the surface of paper) located adjacent to the first LED group 20A in the row-wise direction.

For this reason, in the row-wise direction in the first LED group 20A, magenta light that is emitted from the M-LED chip 13M2 mounted in the LED 10A2 and green light that is emitted from the G-LED chip 13G1 of the LED 10A1 are mixed together to become white light.

Thus, in each of the LED groups 20A, the distance between the G-LED chip 13G1 mounted in the LED 10A1 and the M-LED chip 13M2 mounted in the LED 10A2 is so short that green light emitted from the G-LED chip 13G1 and magenta light emitted from the M-LED chip 13M2 are mixed together to become white light.

For this reason, even if these LED groups 20A are placed at a longer distance from each other in the row-wise direction, color irregularities attributed to the disposition all over the substrate 4 of the plurality of G-LED and M-LED chips that emit plural colors of light can be prevented from appearing. This makes it possible to prevent an increase in cost by reducing the number of LEDs and prevent color irregularities attributed to the disposition of LEDs each including a plurality of LED chips mounted therein.

Thus, the arrangement of LEDs in an odd-numbered row is constituted solely by plural sets of pairs of LEDs 10A1 and 10A2 located adjacent to each other in the row-wise direction.

In particular, color irregularities at an edge Z1 of the backlight 3A are improved by that one of the rows which is constituted by LEDs 10A1 and 10A2 located on the outermost side near the edge Z1 of the backlight 3A. This makes it possible, in particular, to prevent color irregularities in the backlight 3A from being viewed.

Further, among the plurality of LED groups 20A, the LED 10A3 of the first LED group 20A is positioned so that the G-LED chip 13G3 mounted in the LED 10A3 and the M-LED chip 13M1 mounted in the LED 10A1 of the same first LED group 20A are placed at a distance that is shorter than the distance between the G-LED chip 13G3 mounted in the LED 10A3 and the M-LED chip 13M1 of the LED 10A1 of a second LED group 20A (e.g. the lower right LED group 20A as seen from the front of the surface of paper) located adjacent to the first LED group 20A in the column-wise direction.

For this reason, in the column-wise direction in the first LED group 20A, too, green light that is emitted from the G-LED chip 13G3 of the LED 10A3 and magenta light that is emitted from the M-LED chip 13M1 of the LED 10A1 are mixed together to become white light.

For this reason, furthermore, even if the first LED group 20A and the second LED group 20A located adjacent to the first LED group in the column-wise direction are placed at a longer distance from each other in the column-wise direction, too, color irregularities attributed to the disposition of the plurality of G-LED and M-LED chips that emit plural colors of light can be prevented from appearing. This makes it possible to prevent an increase in cost and, at the same time, prevent color irregularities in the backlight 3A including an arrangement of LEDs each including a plurality of G-LED and M-LED chips mounted therein. That is, this makes it possible to prevent an increase in cost by reducing the number of LEDs and prevent color irregularities attributed to the disposition of LEDs each including a plurality of LED chips mounted therein.

Thus, the arrangement of LEDs in an odd-numbered column is constituted solely by plural sets of pairs of LEDs 10A1 and 10A3 located adjacent to each other in the column-wise direction.

In particular color irregularities at an edge Z2 of the backlight 3A are improved by that one of the columns which is constituted by LEDs 10A1 and 10A3 located on the outermost side near the edge Z2 of the backlight 3A. This makes it possible, in particular, to prevent color irregularities in the backlight 3A from being viewed.

Further, the G-LED chip 13G4 mounted in the LED 10A4 of the first LED group 20A and the M-LED chip 13M3 mounted in the LED 10A3 of the first LED group 20A are placed at a distance that is shorter than the distance between the G-LED chip 14G4 mounted in the LED 10A4 of the first LED group 20A and the M-LED chip 13M3 of the LED 10A3 of a second LED group 20A (e.g. the LED group 20A located on the immediate left side of the upper right LED group 20A as seen from the front of the surface of paper) located adjacent to the first LED group 20A in the row-wise direction.

This makes it possible to also prevent color irregularities in the even-numbered rows in which the LEDs 10A3 and 10A4 are alternately arranged, allowing the backlight 3A to be more highly effective in preventing color irregularities.

Thus, the arrangement of LEDs in an even-numbered row is constituted solely by plural sets of pairs of LEDs 10A3 and 10A4 located adjacent to each other in the row-wise direction.

In particular, color irregularities at an edge Z3 of the backlight 3A are improved by that one of the rows which is constituted by LEDs 10A3 and 10A4 located on the outermost side near the edge Z3 of the backlight 3A. This makes it possible, in particular, to prevent color irregularities in the backlight 3A from being viewed.

Further, the arrangement of LEDs in an even-numbered column is constituted solely by plural sets of pairs of LEDs 10A2 and 10A4 located adjacent to each other in the column-wise direction.

In particular, color irregularities at an edge Z4 of the backlight 3A are improved by that one of the columns which is constituted by LEDs 10A2 and 10A4 located on the outermost side near the edge Z4 of the backlight 3A. This makes it possible, in particular, to prevent color irregularities in the backlight 3A from being viewed.

Furthermore, in other words, the LEDs 10A1, 10A2, 10A3, and 10A4 of an LED group 20A may also be expressed as being arranged in rotation symmetry with respect to the central axis surrounded by the LEDs 10A1, 10A2, 10A3, and 10A4. That is, the LEDs 10A1, 10A2, 10A3, and 10A4 are arranged in 90-degree counterclockwise rotation symmetry with respect to the central axis surrounded by the LEDs 10A1, 10A2, 10A3, and 10A4.

This makes it possible to prevent color irregularities by shortening the distance between the G-LED chip 13G1 and the M-LED chip 13M2, the distance between the G-LED chip 13G2 and the M-LED chip 13M4, the distance between the G-LED chip 13G4 and the M-LED chip 13M3, and the distance between the G-LED chip 13G3 and the M-LED chip 13M1 in each of the LED groups 20A.

Further, each of the LEDs 10A1, 10A2, 10A3, and 10A4 includes G-LED and M-LED chips mounted into one package. This makes it possible to change the relative distance between each G-LED chip and the corresponding M-LED chip simply by adjusting the respective positions and angles of the LEDs 10A1, 10A2, 10A3, and 10A4, making it easy to adjust the relative distance between each G-LED chip and the corresponding M-LED chip.

It should be noted that each of the LED groups 20A may include two, three, or five or more LEDs instead of including four LEDs, provided the LEDs are arranged in rotation symmetry with respect to the central axis surrounded by the LEDs. Further, although each of the LEDs 10A1 to 10A4 has been described as being a structure (so-called 2-in-1) including two LED chips mounted into one package, this does not imply any limitation. Each of the LEDs 10A1 to 10A4 may be a structure (so-called 3-in-1) including three LED chips of complementary colors mounted into one package or a structure including four or more LED chips of complementary colors mounted into one package.

(Experimental Results)

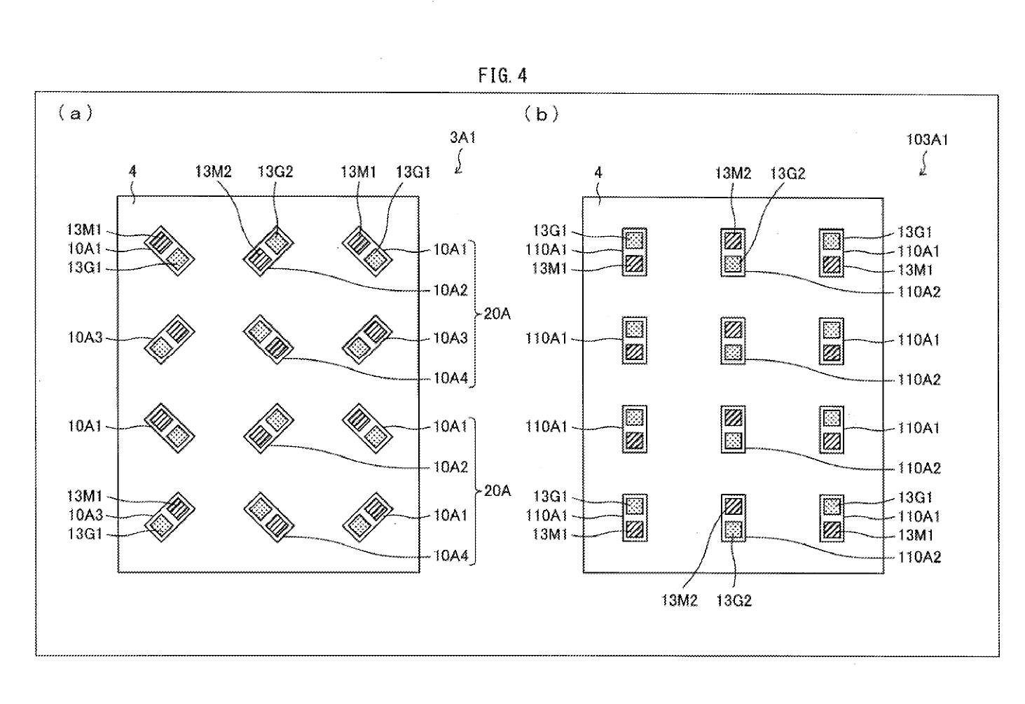

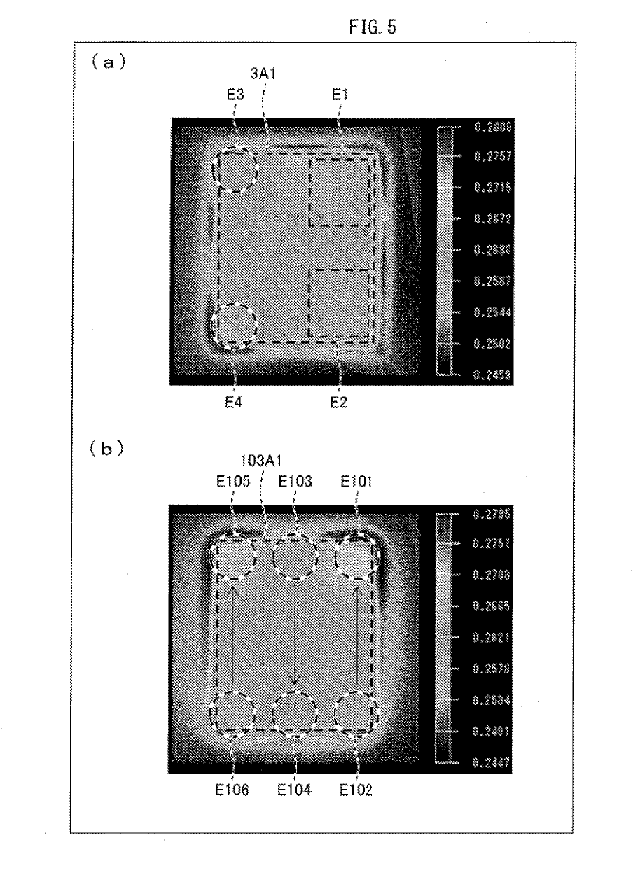

Experimental results are described with reference to FIGS. 4 and 5. Backlights were actually prepared. Each of these backlights included LEDs each including two LED chips of complementary colors mounted into one package. These backlights differed from each other in terms of the positions or angles of their respective LEDs. The respective chromaticities of these backlights were actually measured.

FIG. 4 illustrates a cross-sectional view (a) of a first trial-produced backlight 3A1 as taken along a direction parallel to a flat surface and a cross-sectional view (b) of a second trial-produced backlight 103A1 as taken along a direction parallel to a flat surface.

As shown in (a) and (b) of FIG. 4, each of the backlights 3A1 and 103A1 thus prepared included an arrangement of LEDs in three columns and four rows. It should be noted that, in each of the backlights 3A1 and 103A1 shown in (a) and (b) of FIG. 4, the substrate 4 has longer sides that are parallel to the column-wise direction (i.e. the vertical direction as seen from the front of the surface of paper) and has shorter sides that are orthogonal to the longer sides and parallel to the row-wise direction (i.e. the horizontal direction as seen from the front of the surface of paper).

On the substrate 4 of the backlight 3A1 shown in (a) of FIG. 4, LEDs 10A1, 10A3, 10A1, and 10A3 were arranged in this order from the top in odd-numbered columns (i.e. the first and third columns as counted from the right), and LEDs 10A2, 10A4, 10A2, and 10A4 were arranged in this order from the top in an even-numbered column (i.e. the second column as counted from the right). The first two columns on the right constitute two rows of LED groups 20A each including LEDs 10A1, 10A2, 10A3, and 10A4.

It should be noted that although the leftmost column (i.e. the third column as counted from the right) does not have pairs of LEDs 10A2 and 10A4 located adjacent thereto in the row-wise direction and, as such, does not constitute LED groups 20A, the leftmost column was provided for confirmation of the appearance of color irregularities in the absence of such pairs of LEDs 10A2 and 10A4.

On the substrate 4 of the backlight 103A1 shown in (b) of FIG. 4, four LEDs 110A1 each including G-LED and M-LED chips 13G1 and 13M1 mounted therein were arranged at regular intervals in odd-numbered columns (i.e. the first and third columns as counted from the right). Further, four LEDs 110A2 each including M-LED and G-LED chips 13M2 and 13G2 mounted therein were arranged at regular intervals in an even-numbered column (i.e. the second column as counted from the right).

Each of the LEDs 110A1 has its G-LED and M-LED chips 13G1 and 13M1 located in higher and lower positions, respectively, than each other as seen from the front of the surface of paper. Meanwhile, each of the LEDs 110A2 has its M-LED and G-LED chips 13M2 and 13G2 located in higher and lower positions, respectively, than each other as seen from the front of the surface of paper. The LED 110A1 and 110A2 are arranged at regular intervals in rows and columns so that their longer sides are parallel to each other.

The G-LED and M-LED chips mounted in the LEDs (LEDs 10A1 to 10A4, 110A1, and 110A2) shown in (a) and (b) of FIG. 4 are all the same. Each of the M-LED chips included an LED that emits blue light and a resin with which the LED was sealed, and the resin contained a phosphor that emits red light in response to the blue light.

FIG. 5 illustrates a diagram (a) showing a result of measurement of a chromaticity y in the backlight 3A1 shown in (a) of FIG. 4 and a diagram (b) showing a result of measurement of a chromaticity y in the backlight 103A1 shown in (b) of FIG. 4. The chromaticity y of backlight having passed through a diffusing plate and an optical sheet colors depending on the orientations of the LED packages.

As can be seen in regions E1 and E2 shown in (a) of FIG. 5, the backlight 3A1 is uniform in chromaticity y without a chromaticity difference both in the central part and right edge of the backlight 3A1 since the LEDs 10A1 to 10A4 arranged in the first two columns on the right have their G-LED and M-LED chips placed at such short distances from each other that the colors of the G-LED and M-LED chips are mixed together.

Meanwhile, in the backlight 3A1, as shown in (a) of FIG. 4, the LED 10A1 located at the top in the leftmost column as seen from the front of the surface of paper has its M-LED chip 13M1 oriented to the upper left with no G-LED chip located nearby. For this reason, as shown in (a) of FIG. 5, a region E3 located near the region in which the LED 10A1 is located turns magenta and becomes lower in chromaticity y.

Further, in the backlight 3A1, as shown in (a) of FIG. 4, the LED 10A3 located at the bottom in the leftmost column as seen from the front of the surface of paper has its G-LED chip 13G1 oriented to the lower left with no M-LED chip located nearby. For this reason, as shown in (a) of FIG. 5, a region E4 located near the region in which the LED 10A3 is located turns green and becomes higher in chromaticity y.

This shows that the LEDs 10A1 and 10A3 arranged in the leftmost column and paired with no LEDs located adjacent thereto in the row-wise direction cause color irregularities to appear in the regions E3 and E4 located in corners of the backlight 3A1.

In the backlight 103A1, as shown in (b) of FIG. 4, the LEDs 110A1 were vertically arranged in the odd-numbered columns so that the G-LED and M-LED chips 13G1 and 13M1 of each of the LEDs 110A1 are located in higher and lower positions, respectively, than each other as seen from the front of the surface of paper. For this reason, as shown in (b) of FIG. 5, while there are increases in chromaticity y in a region E101 located in the upper right corner as seen from the front of the surface of paper and a region E105 located in the upper left corner as seen from the front of the surface of paper, there are decreases in chromaticity y in a region E102 located in the lower right corner as seen from the front of the surface of paper and a region E106 located in the lower left corner as seen from the front of the surface of paper.

Further, as shown in (b) of FIG. 4, the LEDs 110A2 were vertically arranged in the even-numbered column so that the M-LED and G-LED chips 131M2 and 13G2 of each of the LEDs 110A2 are located in higher and lower positions, respectively, than each other as seen from the front of the surface of paper. For this reason, as shown in (b) of FIG. 5, while the chromaticity y is small in value in a region E103 located at the upper central edge as seen from the front of the surface of paper, there is an increase in chromaticity y in a region E104 located at the lower central edge as seen from the front of the surface of paper. This shows that chromaticity irregularities (i.e. color irregularities) appear in the plane of the backlight 103A1.

### Embodiment 2

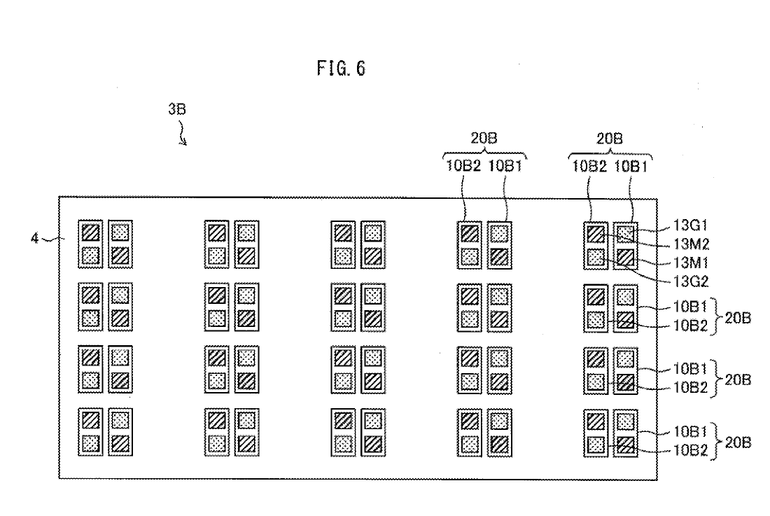

Embodiment 2 of the present invention is described below with reference to FIG. 6. For convenience of explanation, members having the same functions as those described above in Embodiment 1 are given the same reference signs and, as such, are not described below.

FIG. 6 is a cross-sectional view of a backlight (lighting device) 3B according to Embodiment 2 as taken along a direction parallel to a flat surface. The liquid crystal display 1 (see FIGS. 2 and 3) may include the backlight 3B shown in FIG. 6 instead of including the backlight 3A.

The backlight 3B differs from the backlight 3A in that the backlight 3B includes LED groups 20B arranged on the substrate 4 instead of including the LED groups 20A arranged on the substrate 4. In other respect, the backlight 3B is identical in configuration to the backlight 3A.

The plurality of LED groups 20B are mounted on the substrate 4 and arranged in a matrix by being arranged in rows (in the horizontal direction as seen from the front of the surface of paper) and columns (in the vertical direction as seen from the front of the surface of paper) that are orthogonal to the rows. The LED groups 20B are arranged at regular intervals both in rows and columns. Although FIG. 6 shows an example in which the LED groups 20B are arranged in four rows and five columns, the number of LED groups 20B is not limited to this example but may be changed as appropriate according to the size of the backlight 3B and the product in which the backlight 3B is used.

Each of the LED groups 20B includes a plurality of LEDs 10B1 and 10B2 each of which is identical in configuration to the LED 10A (see FIG. 3). The LED (first LED) 10B1 includes a G-LED chip (first LED chip) 13G1 and an M-LED chip (second LED chip) 13M1. The LED (second LED) 10B2 includes an M-LED chip (second LED chip) 13M2 and a G-LED chip (first LED chip) 13G2.

The LED 10B2 is positioned so that the M-LED chip 13M2 is located adjacent to the G-LED chip 13G1 of the LED 10B1 in the row-wise direction and the G-LED chip 13G2 is located adjacent to the M-LED chip M1 of the LED 10B1 in the row-wise direction.

The LEDs 10B1 and 10B2 are arranged so that the direction (longitudinal direction) in which the G-LED and M-LED chips 13G1 and 13M1 of the LED 10B1 are lined up is parallel to the direction (longitudinal direction) in which the M-LED and G-LED chips 13M2 and 13G2 of the LED 10B2 are lined up.

Further, the LEDs 10B1 and 10B2 are arranged so that the G-LED and M-LED chips 13G1 and 13M1 of the LED 10B1 are opposite in arrangement to the M-LED and G-LED chips 13M2 and 13G2 of the LED 10B2. That is, the LEDs 10B1 and 10B2 may also be expressed as being arranged in rotation symmetry with respect to the central axis.

On the substrate 4 of the backlight 3B, the plurality of LED groups 20B each including such an arrangement of LEDs 10B1 and 10B2 are arranged in rows and columns. The backlight 3B includes an arrangement of LEDs in an even number of columns and an even number of rows.

From the column-wise perspective, LEDs 10B1 each including its G-LED and M-LED chips 13G1 and 13M1 located in higher and lower positions, respectively, than each other as seen from the front of the surface of paper are aligned in the rightmost column as seen from the front of the surface of paper. LEDs 10B1 are similarly aligned in an odd-numbered column as counted from the right as seen from the front of the surface of paper.

LEDs 10B2 each including its M-LED and G-LED chips 13M2 and 13G2 located in higher and lower positions, respectively, than each other as seen from the front of the surface of paper are aligned in the second rightmost column as seen from the front of the surface of paper. LEDs 10B2 are similarly aligned in an even-numbered column as counted from the right as seen from the front of the surface of paper.

From the row-wise perspective, in the uppermost row as seen from the front of the surface of paper, as well as in each row, LEDs 10B1 and 10B2 are alternately lined up in this order in a direction from right to left so that their longer sides are parallel to each other.

In other words, the backlight 3B includes an arrangement of LEDs placed opposite in angle to each other for each column and an arrangement of LEDs oriented in the same direction for each row.

Thus, the backlight 3B includes such an arrangement of LEDs 10B1 and 10B2 that the G-LED chips 13G1 mounted in the LEDs 10B1 and the M-LED chips 13M2 mounted in the LEDs 10B2 are located adjacent to each other in the row-wise direction. Further, the M-LED chips 13M1 and the G-LED chips 13G2 are located adjacent to each other in the row-wise direction.

Attention is here focused on a first one (e.g. the upper right LED group 20B as seen from the front of the surface of paper) of the LED groups 20B arranged in rows and columns in the backlight 3B.

The M-LED chip 13M2 mounted in the LED 10B2 of the first LED group 20B and the G-LED chip 13G1 mounted in the LED 10B1 of the same first LED group 20B are placed at a distance that is shorter than the distance between the M-LED chip 13M2 mounted in the LED 10B2 of the first LED group 20B and the G-LED chip 13G1 of the LED 10B1 of a second LED group 20B (e.g. the LED group 20B located on the immediate left side of the upper right LED group 20B as seen from the front of the surface of paper) located adjacent to the first LED group 20B in the row-wise direction.

For this reason, in the row-wise direction in the first LED group 20B, magenta light that is emitted from the M-LED chip 13M2 mounted in the LED 10B2 and green light that is emitted from the G-LED chip 13G1 of the LED 10B1 are mixed together to become white light.

Thus, in each of the LED groups 20B, the distance between the LED chip 13G1 mounted in the LED 10B1 and the M-LED chip 13M2 mounted in the LED 10B2 is so short that green light emitted from the G-LED chip 13G1 and magenta light emitted from the M-LED chip 13M2 are mixed together to become white light.

For this reason, even if these LED groups 20B are placed at a longer distance from each other in the row-wise direction, color irregularities attributed to the disposition all over the substrate 4 of the plurality of G-LED and M-LED chips that emit plural colors of light can be prevented from appearing. This makes it possible to prevent an increase in cost by reducing the number of LEDs and prevent color irregularities attributed to the disposition of LEDs each including a plurality of LED chips mounted therein.

Thus, the arrangement of LEDs in each row is constituted solely by plural sets of pairs of LEDs 10B1 and 10B2 located adjacent to each other in the row-wise direction.

In particular, color irregularities at the edges Z1 and Z3 of the backlight 3B are improved by those two of the rows which are constituted by LEDs 10B1 and 10B2 located on the outermost sides near the edges Z1 and Z3 of the backlight 3B. This makes it possible, in particular, to prevent color irregularities in the backlight 3B from being viewed.

Further, the arrangement of LEDs in an odd-numbered column is constituted solely by plural sets of pairs of LEDs 10B1 located adjacent to each other in the column-wise direction. In particular, color irregularities at an edge Z2 of the backlight 3B are improved by that one of the columns which is constituted by LEDs 10B1 located on the outermost side near the edge Z2 of the backlight 3B. This makes it possible, in particular, to prevent color irregularities in the backlight 3B from being viewed.

Furthermore, the arrangement of LEDs in an even-numbered column is constituted solely by plural sets of pairs of LEDs 10B2 located adjacent to each other in the column-wise direction. In particular, color irregularities at an edge Z4 of the backlight 3B are improved by that one of the columns which is constituted by LEDs 10B2 located on the outermost side near the edge Z4 of the backlight 3B. This makes it possible, in particular, to prevent color irregularities in the backlight 3B from being viewed.

Furthermore, in other words, the LEDs 10B1 and 10B2 of an LED group 20B may also be expressed as being arranged in rotation symmetry with respect to the central axis. That is, the LEDs 10B1 and 10B2 are arranged in 180-degree rotation symmetry with respect to the central axis.

Moreover, the LEDs 10B1 arranged in an odd-numbered column and the LED 10B2 arranged in an even-numbered column are located proximal to each other. This makes it possible to prevent color irregularities in the whole plane by shortening the distance the G-LED chip 13G1 and the M-LED chip 13M2 and the distance between the G-LED chip 13G2 and the M-LED chip 13M11 in each of the LED groups 20B.

Further, each of the LEDs 10B1 and 10B2 includes G-LED and M-LED chips mounted into one package. This makes it possible to change the relative distance between each G-LED chip and the corresponding M-LED chip simply by adjusting the respective positions and angles of the LEDs 10B1 and 10B2, making it easy to adjust the relative distance between each G-LED chip and the corresponding M-LED chip.

It should be noted that the LED chips mounted in each of the LEDs 10B1 and 10B2 are not limited to a G-LED chip and an M-LED chip but need only be LED chips of complementary colors. For example, a B-LED chip that emits blue light and a Y-LED chip that emits yellow light may be mounted into one package, or an R-LED chip that emits red light and a CY-LED chip that emits cyan light may be mounted into one package.

### Embodiment 3

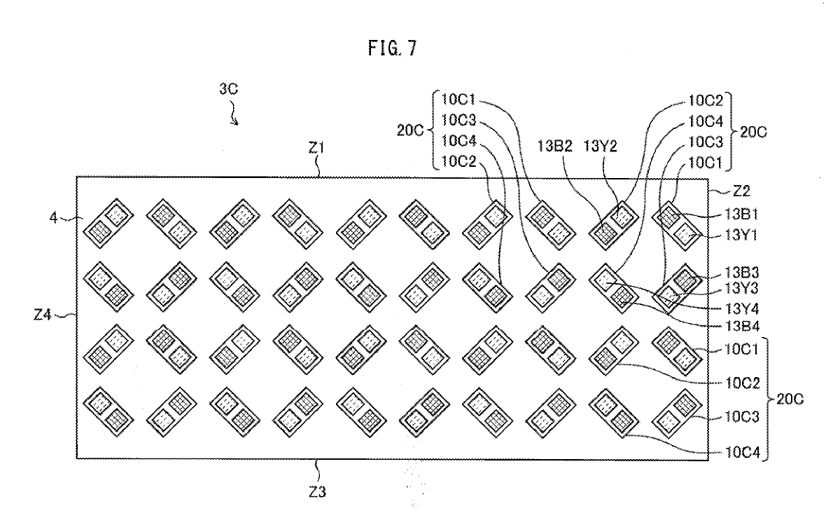

Embodiment 3 of the present invention is described below with reference to FIG. 7. For convenience of explanation, members having the same functions as those described above in Embodiments 1 and 2 are given the same reference signs and, as such, are not described below.

FIG. 7 is a cross-sectional view of a backlight (lighting device) 3C according to Embodiment 3 as taken along a direction parallel to a flat surface. The liquid crystal display 1 (see FIGS. 2 and 3) may include the backlight 3C shown in FIG. 7 instead of including the backlight 3A.

The backlight 3C differs from the backlight 3A in that the backlight 3C includes LED groups 20C arranged on the substrate 4 instead of including the LED groups 20A arranged on the substrate 4. In other respects, the backlight 3C is identical in configuration to the backlight 3A.

Each of the LED groups 20C includes LEDs 10C1, 10C2, 10C3, and 10C4. The LEDs 10C1, 10C2, 10C3, and 10C4 differ from the LEDs 10A1, 10A2, 10A3, and 10A4 in that each of the LEDs 10C1, 10C2, 10C3, and 10C4 includes B-LED (blue LED) and Y-LED (yellow LED) chips of complementary colors that emit blue light and yellow light, respectively, instead of including a G-LED chip and an M-LED chip. In other respects, the LEDs 10C1, 10C2, 10C3, and 10C4 are identical in configuration to the LED 10A1, 10A2, 10A3, and 10A4, including the orientation in which they are arranged on the substrate 4.

The LED groups 20C are arranged at regular intervals both in rows and columns. Although FIG. 7 shows an example in which the LED groups 20C are arranged in two rows and five columns, the number of LED groups 20C is not limited to this example but may be changed as appropriate according to the size of the backlight 3C and the product in which the backlight 3C is used.

The LED (first LED) 10C1 includes a B-LED chip (first LED chip) 13B1 and a Y-LED chip (second LED chip) 13Y1. The LED (second LED) 10C2 includes a B-LED chip (first LED chip) 13B2 and a Y-LED chip (second LED chip) 13Y2. The LED (third LED) 10C3 includes a B-LED chip (first LED chip) 13B3 and a Y-LED chip (second LED chip) 13Y3. The LED (fourth LED) 10C4 includes a B-LED chip (first LED chip) 13B4 and a Y-LED chip (second LED chip) 13Y4. The B-LED chips 13B1, 13B2, 13B3, and 13B4 are LED chips that emit blue light, and the Y-LED chips 13Y1, 13Y2, 13Y3, and 13Y4 are LED chips that emit yellow light.

On the substrate 4 of the backlight 3C, the plurality of LED groups 20C each including LEDs 10C1, 10C2, 10C3, 10C4 are arranged in rows and columns. The backlight 3C includes an arrangement of LEDs in an even number of columns and an even number of rows.

From the column-wise perspective, in the rightmost column as seen from the front of the surface of paper, an LED 10C1 tilted at approximately −45 degrees, an LED 10C3 tilted at approximately 45 degrees, an LED 10C tilted at approximately −45 degrees, and an LED 10C3 tilted at approximately 45 degrees are arranged in this order from top to bottom as seen from the front of the surface of paper. LEDs 10C1 and 10C3 are similarly arranged in an odd-numbered column as counted from the right as seen from the front of the surface of paper. In the second rightmost column as seen from the front of the surface of paper, an LED 10C2 tilted at approximately 45 degrees, an LED 10C4 tilted at approximately −45 degrees, an LED 10C2 tilted at approximately 45 degrees, and an LED 10C4 tilted at approximately −45 degrees are arranged in this order from top to bottom as seen from the front of the surface of paper. LEDs 10C2 and 10C4 are similarly arranged in an even-numbered column as counted from the right as seen from the front of the surface of paper. Thus, the backlight 3C includes an arrangement of LEDs placed opposite in angle to each other every 1 column.

From the row-wise perspective, in the uppermost row as seen from the front of the surface of paper, an LED 10C1 tilted at approximately −45 degrees, an LED 10C2 tilted at approximately 45 degrees, an LED 10C1 tilted at approximately −45 degrees, an LED 10C2 tilted at approximately −45 degrees, . . . , an LED 10C1 tilted at approximately −45 degrees, and an LED 10C2 tilted at approximately 45 degrees are arranged in this order in a direction from right to left. LEDs 10C1 and 10C2 are similarly arranged in an odd-numbered row as counted from the top as seen from the front of the surface of paper. In the second uppermost row as seen from the front of the surface of paper, an LED 10C3 tilted at approximately 45 degrees, an LED 10C4 tilted at approximately −45 degrees, an LED 10C3 tilted at approximately 45 degrees, an LED 10C4 tilted at approximately 45 degrees, . . . , an LED 10C3 tilted at approximately 45 degrees, and an LED 10C4 tilted at approximately −45 degrees are arranged in this order in a direction from right to left. LEDs 10C3 and 10C4 are similarly arranged in an even-numbered row as counted from the top as seen from the front of the surface of paper. Thus, the backlight 3C includes an arrangement of LEDs placed opposite in angle to each other every 1 row.

Thus, the backlight 3C includes such an arrangement of LEDs 10C1 and 10C2 that the B-LED chips 13B1 mounted in the LEDs 10C1 and the Y-LED chips 13Y2 mounted in the LEDs 10C2 are located adjacent to each other in the row-wise direction. Further, the Y-LED chips 13Y1 and the B-LED chips 13B2 are located adjacent to each other in the row-wise direction.

Attention is here focused on a first one (e.g. the upper right LED group 20C as seen from the front of the surface of paper) of the LED groups 20C arranged in rows and columns in the backlight 3C.

The Y-LED chip 13Y2 mounted in the LED 10C2 of the first LED group 20C and the B-LED chip 13B1 mounted in the LED 10C1 of the same first LED group 20C are placed at a distance that is shorter than the distance between the Y-LED chip 13Y2 mounted in the LED 10C2 of the first LED group 20C and the B-LED chip 13B1 of the LED 10C1 of a second LED group 20C (e.g. the LED group 20C located on the immediate left side of the upper right LED group 20C as seen from the front of the surface of paper) located adjacent to the first LED group 20C in the row-wise direction.

For this reason, in the row-wise direction in the first LED group 20C, yellow light that is emitted from the Y-LED chip 13Y2 mounted in the LED 10C2 and blue light that is emitted from the B-LED chip 13B1 of the LED 10C1 are mixed together to become white light.

Thus, in each of the LED groups 20C, the distance between the B-LED chip 13B1 mounted in the LED 10C1 and the Y-LED chip 13Y2 mounted in the LED 10C2 is so short that blue light emitted from the B-LED chip 13B1 and yellow light emitted from the Y-LED chip 13Y2 are mixed together to become white light.

For this reason, even if these LED groups 20C are placed at a longer distance from each other in the row-wise direction, color irregularities attributed to the disposition all over the substrate 4 of the plurality of B-LED and Y-LED chips that emit plural colors of light can be prevented from appearing. This makes it possible to prevent an increase in cost by reducing the number of LEDs and prevent color irregularities attributed to the disposition of LEDs each including a plurality of LED chips mounted therein.

Thus, the arrangement of LEDs in an odd-numbered row is constituted solely by plural sets of pairs of LEDs 10C1 and 10C2 located adjacent to each other in the row-wise direction.

In particular, color irregularities at an edge Z1 of the backlight 3C are improved by that one of the rows which is constituted by LEDs 10C1 and 10C2 located on the outermost side near the edge Z1 of the backlight 3C. This makes it possible, in particular, to prevent color irregularities in the backlight 3C from being viewed.

Further, among the plurality of LED groups 20C, the LED 10C3 of the first LED group 20C is positioned so that the B-LED chip 13B3 mounted in the LED 10C3 and the Y-LED chip 13Y1 mounted in the LED 10C1 of the same first LED group 20C are placed at a distance that is shorter than the distance between the B-LED chip 13B3 mounted in the LED 10C3 and the Y-LED chip 13Y1 of the LED 10C1 of a second LED group 20C (e.g. the lower right LED group 20C as seen from the front of the surface of paper) located adjacent to the first LED group 20C in the column-wise direction.

For this reason, in the column-wise direction in the first LED group 20C, too, blue light that is emitted from the B-LED chip 13B3 of the LED 10C3 and yellow light that is emitted from the Y-LED chip 13Y1 of the LED 10C1 are mixed together to become white light.

For this reason, furthermore, even if the first LED group 20C and the second LED group 20C located adjacent to the first LED group in the column-wise direction are placed at a longer distance from each other in the column-wise direction, too, color irregularities attributed to the disposition of the plurality of B-LED and Y-LED chips that emit plural colors of light can be prevented from appearing. This makes it possible to prevent an increase in cost and, at the same time, prevent color irregularities in the backlight 3C including an arrangement of LEDs each including a plurality of B-LED and Y-LED chips mounted therein. That is, this makes it possible to prevent an increase in cost by reducing the number of LEDs and prevent color irregularities attributed to the disposition of LEDs each including a plurality of LED chips mounted therein.

Thus, the arrangement of LEDs in an odd-numbered column is constituted solely by plural sets of pairs of LEDs 10C1 and 10C3 located adjacent to each other in the column-wise direction.

In particular, color irregularities at an edge Z2 of the backlight 3C are improved by that one of the columns which is constituted by LEDs 10C1 and 10C3 located on the outermost side near the edge Z2 of the backlight 3C. This makes it possible, in particular, to prevent color irregularities in the backlight 3C from being viewed.

Further, the B-LED chip 13B4 mounted in the LED 10C4 of the first LED group 20C and the Y-LED chip 13Y3 mounted in the LED 10C3 of the first LED group 20C are placed at a distance that is shorter than the distance between the B-LED chip 14B4 mounted in the LED 10C4 of the first LED group 20C and the Y-LED chip 13Y3 of the LED 10C3 of a second LED group 20C (e.g. the LED group 20C located on the immediate left side of the upper right LED group 20C as seen from the front of the surface of paper) located adjacent to the first LED group 20C in the row-wise direction.

This makes it possible to also prevent color irregularities in the even-numbered rows in which the LEDs 10C3 and 10C4 are alternately arranged, allowing the backlight 3C to be more highly effective in preventing color irregularities.

Thus, the arrangement of LEDs in an even-numbered row is constituted solely by plural sets of pairs of LEDs 10C3 and 10C4 located adjacent to each other in the row-wise direction.

In particular, color irregularities at an edge Z3 of the backlight 3C are improved by that one of the rows which is constituted by LEDs 10C3 and 10C4 located on the outermost side near the edge Z3 of the backlight 3C. This makes it possible, in particular, to prevent color irregularities in the backlight 3C from being viewed.

Further, the arrangement of LEDs in an even-numbered column is constituted solely by plural sets of pairs of LEDs 10C2 and 10C4 located adjacent to each other in the column-wise direction.

In particular, color irregularities at an edge Z4 of the backlight 3C are improved by that one of the columns which is constituted by LEDs 10C2 and 10C4 located on the outermost side near the edge Z4 of the backlight 3C. This makes it possible, in particular, to prevent color irregularities in the backlight 3C from being viewed.

Furthermore, in other words, the LEDs 10C1, 10C2, 10C3, and 10C4 of an LED group 20C may also be expressed as being arranged in rotation symmetry with respect to the central axis surrounded by the LEDs 10C1, 10C2, 10C3, and 10C4. That is, the LEDs 10C1, 10C2, 10C3, and 10C4 are arranged in 90-degree counterclockwise rotation symmetry with respect to the central axis surrounded by the LEDs 10C1, 10C2, 10C3, and 10C4.

This makes it possible to prevent color irregularities by shortening the distance between the B-LED chip 13B1 and the Y-LED chip 13Y2, the distance between the B-LED chip 13B2 and the Y-LED chip 13Y4, the distance between the B-LED chip 13B4 and the Y-LED chip 13Y3, and the distance between the B-LED chip 13B3 and the Y-LED chip 13Y1 in each of the LED groups 20C.

It should be noted that each of the LED groups 20C may include two, three, or five or more LEDs instead of including four LEDs, provided the LEDs are arranged in rotation symmetry with respect to the central axis surrounded by the LEDs.

### Embodiment 4

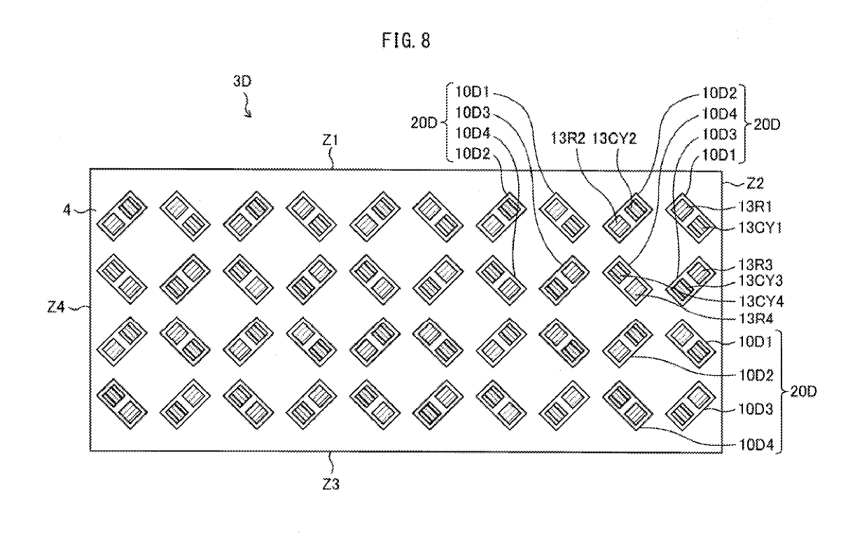

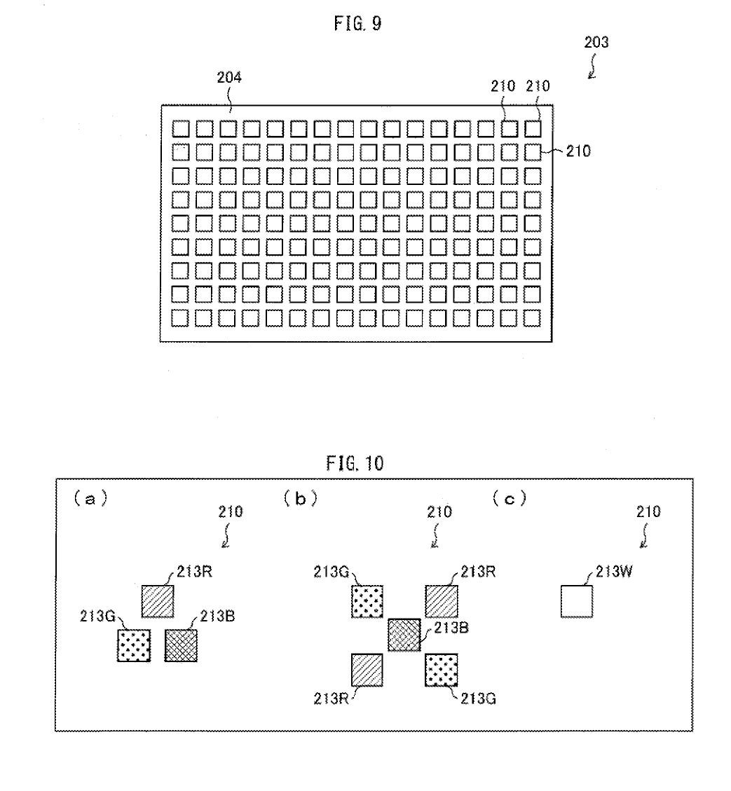

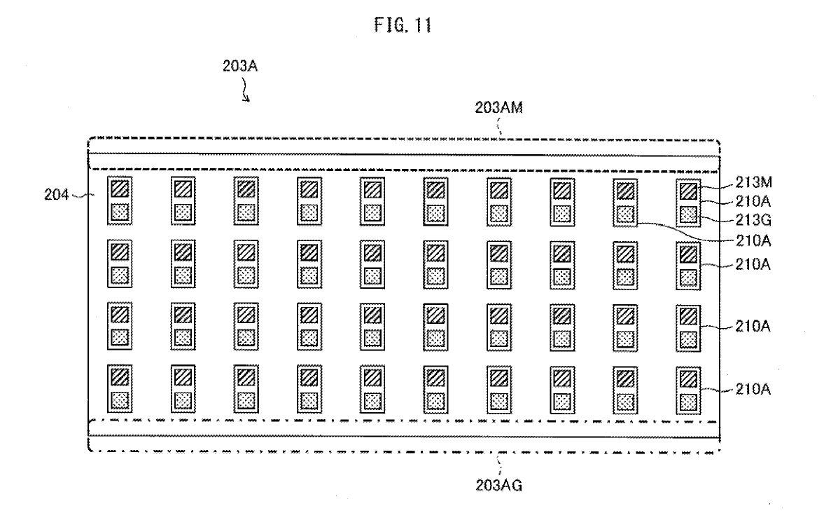

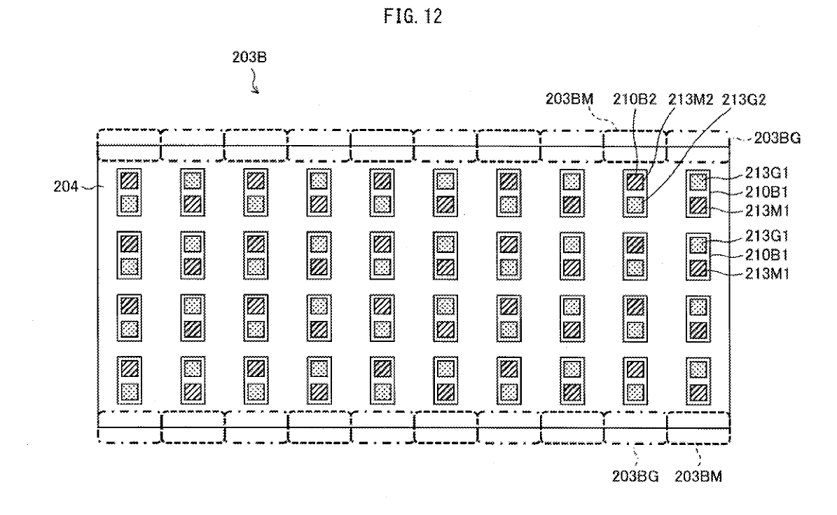

Embodiment 4 of the present invention is described below with reference to FIG. 8. For convenience of explanation, members having the same functions as those described above in Embodiments 1 and 3 are given the same reference signs and, as such, are not described below.

FIG. 8 is a cross-sectional view of a backlight (lighting device) 3D according to Embodiment 4 as taken along a direction parallel to a flat surface. The liquid crystal display 1 (see FIGS. 2 and 3) may include the backlight 3D shown in FIG. 8 instead of including the backlight 3A.

The backlight 3D differs from the backlight 3C (see FIG. 7) in that the backlight 3D includes LED groups 20D arranged on the substrate 4 instead of including the LED groups 20C arranged on the substrate 4. In other respects, the backlight 3D is identical in configuration to the backlight 3C.

Each of the LED groups 20D includes LEDs 10D1, 10D2, 10D3, and 10D4. The LEDs 10D1, 10D2, 10D3, and 10D4 differ from the LEDs 10C1, 10C2, 10C3, and 10C4 in that each of the LEDs 10D1, 10D2, 10D3, and 10D4 includes R-LED (red LED) and CY-LED (cyan LED) chips of complementary colors that emit red light and cyan light, respectively, instead of including a B-LED chip and a Y-LED chip. In other respects, the LEDs 10D1, 10D2, 10D3, and 10D4 are identical in configuration to the LEDs 10C1, 10C2, 10C3, and 10C4, including the orientation in which they are arranged on the substrate 4.

The LED groups 20D are arranged at regular intervals both in rows and columns. Although FIG. 8 shows an example in which the LED groups 20D are arranged in two rows and five columns, the number of LED groups 20D is not limited to this example but may be changed as appropriate according to the size of the backlight 3D and the product in which the backlight 3D is used.

The LED (first LED) 10D1 includes an R-LED chip (first LED chip) 13R1 and a CY-LED chip (second LED chip) 13CY1. The LED (second LED) 10D2 includes an R-LED chip (first LED chip) 13R2 and a CY-LED chip (second LED chip) 13CY2. The LED (third LED) 10D3 includes an R-LED chip (first LED chip) 13R3 and a CY-LED chip (second LED chip) 13CY3. The LED (fourth LED) 10D4 includes an R-LED chip (first LED chip) 13R4 and a CY-LED chip (second LED chip) 13CY4. The R-LED chips 13R1, 13R2, 13R3, and 13R4 are LED chips that emit red light, and the CY-LED chips 13CY1, 13CY2, 13CY3, and 13CY4 are LED chips that emit cyan light.

On the substrate 4 of the backlight 3D, the plurality of LED groups 20D each including LEDs 10D1, 10D2, 10D3, 10D4 are arranged in rows and columns. The backlight 3D includes an arrangement of LEDs in an even number of columns and an even number of rows.

From the column-wise perspective, in the rightmost column as seen from the front of the surface of paper, an LED 10D1 tilted at approximately −45 degrees, an LED 10D3 tilted at approximately 45 degrees, an LED 10D1 tilted at approximately −45 degrees, and an LED 10D3 tilted at approximately 45 degrees are arranged in this order from top to bottom as seen from the front of the surface of paper. LEDs 10D1 and 10D3 are similarly arranged in an odd-numbered column as counted from the right as seen from the front of the surface of paper. In the second rightmost column as seen from the front of the surface of paper, an LED 10D2 tilted at approximately 45 degrees, an LED 10D4 tilted at approximately −45 degrees, an LED 10D2 tilted at approximately 45 degrees, and an LED 10D4 tilted at approximately −45 degrees are arranged in this order from top to bottom as seen from the front of the surface of paper. LEDs 10D2 and 10D4 are similarly arranged in an even-numbered column as counted from the right as seen from the front of the surface of paper. Thus, the backlight 3D includes an arrangement of LEDs placed opposite in angle to each other every 1 column.

From the row-wise perspective, in the uppermost row as seen from the front of the surface of paper, an LED 10D1 tilted at approximately −45 degrees, an LED 10D2 tilted at approximately 45 degrees, an LED 10D1 tilted at approximately −45 degrees, an LED 10D2 tilted at approximately −45 degrees . . . an LED 10D1 tilted at approximately −45 degrees, and an LED 10D2 tilted at approximately 45 degrees are arranged in this order in a direction from right to left. LEDs 10D1 and 10D2 are similarly arranged in an odd-numbered row as counted from the top as seen from the front of the surface of paper. In the second uppermost row as seen from the front of the surface of paper, an LED 10D3 tilted at approximately 45 degrees, an LED 10D4 tilted at approximately −45 degrees, an LED 10D3 tilted at approximately 45 degrees, an LED 10D4 tilted at approximately 45 degrees, . . . , an LED 10D3 tilted at approximately 45 degrees, and an LED 10D4 tilted at approximately −45 degrees are arranged in this order in a direction from right to left. LEDs 10D3 and 10D4 are similarly arranged in an even-numbered row as counted from the top as seen from the front of the surface of paper. Thus, the backlight 3D includes an arrangement of LEDs placed opposite in angle to each other every 1 row.

Thus, the backlight 3D includes such an arrangement of LEDs 10D1 and 10D2 that the R-LED chips 13R1 mounted in the LEDs 10D1 and the CY-LED chips 13CY2 mounted in the LEDs 10D2 are located adjacent to each other in the row-wise direction. Further, the CY-LED chips 13CY1 and the R-LED chips 13R2 are located adjacent to each other in the row-wise direction.

Attention is here focused on a first one (e.g. the upper right LED group 20D as seen from the front of the surface of paper) of the LED groups 20D arranged in rows and columns in the backlight 3D.

The CY-LED chip 13CY2 mounted in the LED 10D2 of the first LED group 20D and the R-LED chip 13R1 mounted in the LED 10D1 of the same first LED group 20D are placed at a distance that is shorter than the distance between the CY-LED chip 13CY2 mounted in the LED 10D2 of the first LED group 20D and the R-LED chip 13R1 of the LED 10D1 of a second LED group 20D (e.g. the LED group 20D located on the immediate left side of the upper right LED group 20D as seen from the front of the surface of paper) located adjacent to the first LED group 20D in the row-wise direction.

For this reason, in the row-wise direction in the first LED group 20D, cyan light that is emitted from the CY-LED chip 13CY2 mounted in the LED 10D2 and red light that is emitted from the R-LED chip 13R1 of the LED 10D1 are mixed together to become white light.

Thus, in each of the LED groups 20D, the distance between the R-LED chip 13R1 mounted in the LED 10D1 and the CY-LED chip 13CY2 mounted in the LED 10D2 is so short that red light emitted from the R-LED chip 13R1 and cyan light emitted from the CY-LED chip 13CY2 are mixed together to become white light.

For this reason, even if these LED groups 20D are placed at a longer distance from each other in the row-wise direction, color irregularities attributed to the disposition all over the substrate 4 of the plurality of R-LED and CY-LED chips that emit plural colors of light can be prevented from appearing. This makes it possible to prevent an increase in cost by reducing the number of LEDs and prevent color irregularities attributed to the disposition of LEDs each including a plurality of LED chips mounted therein.

Thus, the arrangement of LEDs in an odd-numbered row is constituted solely by plural sets of pairs of LEDs 10D1 and 10D2 located adjacent to each other in the row-wise direction.

In particular, color irregularities at an edge Z1 of the backlight 3D are improved by that one of the rows which is constituted by LEDs 10D1 and 10D2 located on the outermost side near the edge Z1 of the backlight 3D. This makes it possible, in particular, to prevent color irregularities in the backlight 3D from being viewed.

Further, among the plurality of LED groups 20D, the LED 10D3 of the first LED group 20D is positioned so that the R-LED chip 13R3 mounted in the LED 10D3 and the CY-LED chip 13CY1 mounted in the LED 10D1 of the same first LED group 20D are placed at a distance that is shorter than the distance between the R-LED chip 13R3 mounted in the LED 10D3 and the CY-LED chip 13CY1 of the LED 10D1 of a second LED group 20D (e.g. the lower right LED group 20D as seen from the front of the surface of paper) located adjacent to the first LED group 20D in the column-wise direction.

For this reason, in the column-wise direction in the first LED group 20D, too, red light that is emitted from the R-LED chip 13R3 of the LED 10D3 and cyan light that is emitted from the CY-LED chip 13CY1 of the LED 10D1 are mixed together to become white light.

For this reason, furthermore, even if the first LED group 20D and the second LED group 20D located adjacent to the first LED group in the column-wise direction are placed at a longer distance from each other in the column-wise direction, too, color irregularities attributed to the disposition of the plurality of R-LED and CY-LED chips that emit plural colors of light can be prevented from appearing. This makes it possible to prevent an increase in cost and, at the same time, prevent color irregularities in the backlight 3C including an arrangement of LEDs each including a plurality of R-LED and CY-LED chips mounted therein. That is, this makes it possible to prevent an increase in cost by reducing the number of LEDs and prevent color irregularities attributed to the disposition of LEDs each including a plurality of LED chips mounted therein.

Thus, the arrangement of LEDs in an odd-numbered column is constituted solely by plural sets of pairs of LEDs 10D1 and 10D3 located adjacent to each other in the column-wise direction.

In particular, color irregularities at an edge Z2 of the backlight 3D are improved by that one of the columns which is constituted by LEDs 10D1 and 10D3 located on the outermost side near the edge Z2 of the backlight 3D. This makes it possible, in particular, to prevent color irregularities in the backlight 3D from being viewed.

Further, the R-LED chip 13R4 mounted in the LED 10D4 of the first LED group 20D and the CY-LED chip 13CY3 mounted in the LED 10D3 of the first LED group 20D are placed at a distance that is shorter than the distance between the R-LED chip 13R4 mounted in the LED 10D4 of the first LED group 20D and the CY-LED chip 13CY3 of the LED 10D3 of a second LED group 20D (e.g. the LED group 20D located on the immediate left side of the upper right LED group 20D as seen from the front of the surface of paper) located adjacent to the first LED group 20D in the row-wise direction.

This makes it possible to also prevent color irregularities in the even-numbered rows in which the LEDs 10D3 and 10D4 are alternately arranged, allowing the backlight 3D to be more highly effective in preventing color irregularities.

Thus, the arrangement of LEDs in an even-numbered row is constituted solely by plural sets of pairs of LEDs 10D3 and 10D4 located adjacent to each other in the row-wise direction.

In particular, color irregularities at an edge Z3 of the backlight 3D are improved by that one of the rows which is constituted by LEDs 10D3 and 10D4 located on the outermost side near the edge Z3 of the backlight 3D. This makes it possible, in particular, to prevent color irregularities in the backlight 3D from being viewed.

Further, the arrangement of LEDs in an even-numbered column is constituted solely by plural sets of pairs of LEDs 10D2 and 10D4 located adjacent to each other in the column-wise direction.

In particular, color irregularities at an edge Z4 of the backlight 3D are improved by that one of the columns which is constituted by LEDs 10D2 and 10D4 located on the outermost side near the edge Z4 of the backlight 3D. This makes it possible, in particular, to prevent color irregularities in the backlight 3D from being viewed.

Furthermore, in other words, the LEDs 10D1, 10D2, 10D3, and 10D4 of an LED group 20D may also be expressed as being arranged in rotation symmetry with respect to the central axis surrounded by the LEDs 10D1, 10D2, 10D3, and 10D4. That is, the LEDs 10D1, 10D2, 10D3, and 10D4 are arranged in 90-degree counterclockwise rotation symmetry with respect to the central axis surrounded by the LEDs 10D1, 10D2, 10D3, and 10D4.

This makes it possible to prevent color irregularities by shortening the distance between the R-LED chip 13R1 and the CY-LED chip 13CY2, the distance between the R-LED chip 13R2 and the CY-LED chip 13CY4, the distance between the R-LED chip 13R4 and the CY-LED chip 13CY3, and the distance between the R-LED chip 13R3 and the CY-LED chip 13CY1 in each of the LED groups 20D.

It should be noted that each of the LED groups 20D may include two, three, or five or more LEDs instead of including four LEDs, provided the LEDs are arranged in rotation symmetry with respect to the central axis surrounded by the LEDs.

### CONCLUSION

A lighting device (backlight 3A to 3D) according to Aspect 1 of the present invention includes a plurality of LED groups 20A to 20D arranged in rows and columns, the plurality of LED groups 20A to 20D each including first and second LEDs (LED 10A1, 10B1, 10C1, 10D1 and LED 10A2, 10B2, 10C2, 10D2). In the lighting device (backlight 3A to 3D), each of the first and second LEDs (LED 10A1, 10B1, 10C1, 10D1 and LED 10A2, 10B2, 10C2, 10D2) includes first and second LED chips (G-LED chip 13G1, 13G2, B-LED chip 13B1, 13B2, or R-LED chip 13R1, 13R2 and M-LED chip 13M1, 13M2, Y-LED chip 13Y1, 13Y2, or CY-LED chip 13CY1, 13CY2) that emit different colors of light that become white by being mixed together, the first and second LEDs (LED 10A1, 10B1, 10C1, 10D1 and LED 10A2, 10B2, 10C2, 10D2) are arranged so that their respective first and second LED chips (G-LED chip 13G1, 13G2, B-LED chip 13B1, 13B2, or R-LED chip 13R1, 13R2 and M-LED chip 13M1, 13M2, Y-LED chip 13Y1, 13Y2, or CY-LED chip 13CY1, 13CY2) are located adjacent to each other in a row-wise direction, and the second LED (LED 10A2, 10B2, 10C2, 10D2) of a first one 20A to 20D of the LED groups 20A to 20D is positioned so that a distance between the second LED chip (M-LED chip 13M2, Y-LED chip 13Y2. CY-LED chip 13CY2) of the second LED (LED 10A2, 10B2, 10C2, 10D2) and the first LED chip (G-LED chip 13G1, B-LED chip 13B1, R-LED chip 13R1) of the first LED (LED 10A1, 10B1, 10C1, 10D1) of the first LED group 20A to 20D is shorter than a distance between the second LED chip (M-LED chip 13M2, Y-LED chip 13Y2, CY-LED chip 13CY2) of the second LED (LED 10A2, 10B2, 10C2, 10D2) and the first LED chip (G-LED chip 13G1, B-LED chip 13B1, R-LED chip 13R1) of the first LED (LED 10A1, 10B1, 10C1, 10D1) of a second LED group 20A to 20D located adjacent to the first LED group 20A to 20D in the row-wise direction.

According to the foregoing configuration, each of the first and second LEDs includes first and second LED chips that emit different colors to light that become white by being mixed together. This makes it possible to make it cost less than in a case where the first and second LED chips are separately arranged.

Furthermore, according to the foregoing configuration, the distance between the second LED chip of the second LED of the first LED group and the first LED chip of the first LED of the first LED group is shorter than the distance between the second LED chip of the second LED of the first LED group and the first LED chip of the first LED of the second LED group located adjacent to the first LED group in the row-wise direction. For this reason, in the row-wise direction in the first LED group, the color of light that is emitted from the second LED chip of the second LED and the color of light that is emitted from the first LED chip of the first LED are mixed together to become white light.

For this reason, even if the first and second LED groups are placed at a longer distance from each other at least in the row-wise direction, color irregularities attributed to the disposition of the plurality of LED chips that emit plural colors of light can be prevented from appearing. This makes it possible to prevent an increase in cost and, at the same time, prevent color irregularities in a lighting device including an arrangement of LEDs each including a plurality of LED chips mounted therein.

In Aspect 1, a lighting device (backlight 3A to 3D) according to Aspect 2 of the present invention is preferably configured such that, in each of the LED groups 20A to 20D, the first LED (LED 10A1, 10B1, 10C1, 10D1) and the second LED (LED 10A2, 10B2, 10C2, 10D2) are arranged in rotation symmetry. This makes it possible to prevent color irregularities by shortening the distance between the first LED chip and the second LED chip in each of the LED groups. Furthermore, since each of the first and second LEDs includes the first LED chip and the second LED chip, it is possible to change the relative distance between the adjacent first and second LED chip simply by adjusting the respective angles of the first and second LEDs, making it easy to adjust the distance between the first and second LED chips.

In Aspect 1 or 2, a lighting device (backlight 3A. 3C. 3D) according to Aspect 3 of the present invention is preferably configured such that the plurality of LED groups 20A, 20C. 20D each further include a third LED (LED 10A3, 10C3, 10D3) including the first and second LED chips (G-LED chip 13G3, B-LED chip 13B3, or R-LED chip 13R3 and M-LED chip 13M3, Y-LED chip 13Y3, or CY-LED chip 13CY3), and the third LED (LED 10A3, 10C3, 10D3) of the first LED group 20A. 20C, 20D is positioned so that a distance between the first LED chip (G-LED chip 13G3, B-LED chip 13B3, R-LED chip 13R3) of the third LED (LED 10A3, 10C3, 10D3) and the second LED chip (M-LED chip 13M1, Y-LED chip 13Y1, or CY-LED chip 13CY1) of the first LED (LED 10A1, 10C1, 10D1) of the first LED group 20A. 20C, 20D is shorter than a distance between the first LED chip (G-LED chip 13G3, B-LED chip 13B3, R-LED chip 13R3) of the third LED (LED 10A3, 10C3, 10D3) and the second LED chip (M-LED chip 13M1, Y-LED chip 13Y1, or CY-LED chip 13CY1) of the first LED (LED 10A1, 10C1, 10D1) of a second LED group 20A, 20C. 20D located adjacent to the first LED group 20A, 20C, 20D in a column-wise direction.

According to the foregoing configuration, the distance between the first LED chip of the third LED of the first LED group and the second LED chip of the first LED of the first LED group is shorter than the distance between the first LED chip of the third LED of the first LED group and the second LED chip of the first LED of the second LED group located adjacent to the first LED group in the column-wise direction. For this reason, in the column-wise direction in the first LED group, too, the color of light that is emitted from the first LED chip of the third LED and the color of light that is emitted from the second LED chip of the first LED are mixed together to become white light.

For this reason, furthermore, even if the first LED group and the second LED group located adjacent to the first LED group in the column-wise direction are placed at a longer distance from each other in the column-wise direction, too, color irregularities attributed to the disposition of the plurality of LED chips that emit plural colors of light can be prevented from appearing. This makes it possible to prevent an increase in cost and, at the same time, prevent color irregularities in a lighting device including an arrangement of LEDs each including a plurality of LED chips mounted therein.

In Aspect 3, a lighting device (backlight 3A, 3C, 3D) according to Aspect 4 of the present invention is preferably configured such that the plurality of LED groups 20A. 20C. 20D each further include a fourth LED (LED 10A4, 10C4, 10D4) including the first and second LED chips (G-LED chip 13G4, B-LED chip 13B4, or R-LED chip 13R4 and M-LED chip 13M4, Y-LED chip 13Y4, or CY-LED chip 13CY4), and the fourth LED (LED 10A4, 10C4, 10D4) of the first LED group 20A. 20C, 20D is positioned so that a distance between the first LED chip (G-LED chip 13G4, B-LED chip 13B4, or R-LED chip 13R4) of the fourth LED (LED 10A4, 10C4, 10D4) and the second LED chip (M-LED chip 13M4, Y-LED chip 13Y4, or CY-LED chip 13CY4) of the third LED (LED 10A3, 10C3, 10D3) of the first LED group 20A, 20C, 20D is shorter than a distance between the first LED chip (G-LED chip 13G4, B-LED chip 13B4, or R-LED chip 13R4) of the fourth LED (LED 10A4, 10C4, 10D4) and the second LED chip (M-LED chip 13M4, Y-LED chip 13Y4, or CY-LED chip 13CY4) of the third LED (LED 10A3, 10C3, 10D3) of the second LED group 20A. 20C, 20D located adjacent to the first LED group 20A, 20C, 20D in the row-wise direction.

The foregoing configuration makes it possible to also prevent color irregularities in the rows in which the third and fourth LEDs are arranged, allowing the lighting device to be more highly effective in preventing color irregularities.

In Aspect 4, a lighting device (backlight 3A. 3C. 3D) according to Aspect 5 of the present invention is preferably configured such that the first LED (LED 10A1, 10C1, 10D1), the second LED (LED 10A2, 10C2, 10D2), the third LED (LED 10A3, 10C3, 10D3), and the fourth LED (LED 10A4, 10C4, 10D4) are arranged in rotation symmetry.

This makes it possible to prevent color irregularities by shortening the distance between the first LED chip and the second LED chip in each of the LED groups. Furthermore, since each of the first and second LEDs includes the first LED chip and the second LED chip, it is possible to change the relative distance between the adjacent first and second LED chip simply by adjusting the respective angles of the first and second LEDs, making it easy to adjust the distance between the first and second LED chips.

In Aspect 1 or 2, a lighting device (backlight 3B) according to Aspect 6 of the present invention is preferably configured such that the second LED (LED 10B2) of the first LED group 20B is positioned so that a distance between the first LED chip (G-LED chip 13G2) of the second LED (LED 10B2) and the second LED chip (M-LED chip 13M1) of the first LED (LED 10B1) of the first LED group 20B is shorter than a distance between the first LED chip (G-LED chip 13G2) of the second LED (LED 10B2) and the second LED chip (M-LED chip 13M1) of the first LED (LED 10B1) of the second LED group 20B located adjacent to the first LED group 20B in the row-wise direction.

According to the foregoing configuration, in the first LED group, the distance between the first LED chip and the second LED chip is so short that the colors of light that are emitted from the respective LED chips are mixed together to become white. Further, even if the first LED group and the second LED group located adjacent to the first LED group in the row-wise direction are placed at a longer distance from each other, the appearance of color irregularities can be prevented. This makes it possible to prevent an increase in cost and, at the same time, prevent color irregularities in a lighting device including an arrangement of LEDs each including a plurality of LED chips mounted therein.

In Aspects 1 to 6, a display device (liquid crystal display 1) according to Aspect 7 of the present invention preferably includes: the lighting device (backlight 3A to 3D); and a liquid crystal panel 2 that is illuminated by the lighting device (backlight 3A to 3D). The foregoing configuration makes it possible to prevent color irregularities in a display screen while preventing an increase in cost.

The present invention is not limited to the description of the embodiments above, but may be altered within the scope of the claims. An embodiment based on a proper combination of technical means disclosed in different embodiments is encompassed in the technical scope of the present invention. Furthermore, a new technical feature may be formed by combining technical means disclosed in each separate embodiment.

### INDUSTRIAL APPLICABILITY

The present invention is applicable to a lighting device and a display device.

### REFERENCE SIGNS LIST

1 Liquid crystal display (display device)
2 Liquid crystal panel
3A to 3D Backlight (lighting device)
3A1, 103A1 Backlight
4 Substrate
10A1, 10B1, 10C1, 10D1 LED (first LED)
10A2, 10B2, 10C2, 10D2 LED (second LED)
10A3, 10C3, 10D3 LED (third LED)
10A4, 10C4, 10D4 LED (fourth LED)
11 Substrate
12 Package section
13G1 to 13G4 G-LED chip (first LED chip)
13B1 to 13B4 B-LED chip (first LED chip)
13R1 to 13R4 R-LED chip (first LED chip)
13M1 to 13M4 M-LED chip (second LED chip)
13Y1 to 13Y4 Y-LED chip (second LED chip)
13CY1 to 13CY4 CY-LED chip (second LED chip)
15 Electrode
20A to 20D LED group
Z1 to Z4 Edge

1. A lighting device comprising a plurality of LED groups arranged in rows and columns, the plurality of LED groups each including first and second LEDs,
wherein each of the first and second LEDs includes first and second LED chips that emit different colors of light that become white by being mixed together,
the first and second LEDs are arranged so that their respective first and second LED chips are located adjacent to each other in a row-wise direction, and
the second LED of a first one of the LED groups is positioned so that a distance between the second LED chip of the second LED and the first LED chip of the first LED of the first LED group is shorter than a distance between the second LED chip of the second LED and the first LED chip of the first LED of a second LED group located adjacent to the first LED group in the row-wise direction.

2. The lighting device according to claim 1, wherein, in each of the LED groups, the first LED and the second LED are arranged in rotation symmetry.

3. The lighting device according to claim 1, wherein the plurality of LED groups each further include a third LED including the first and second LED chips, and
the third LED of the first LED group is positioned so that a distance between the first LED chip of the third LED and the second LED chip of the first LED of the first LED group is shorter than a distance between the first LED chip of the third LED and the second LED chip of the first LED of a second LED group located adjacent to the first LED group in a column-wise direction.

4. The lighting device according to claim 3, wherein the plurality of LED groups each further include a fourth LED including the first and second LED chips, and
the fourth LED of the first LED group is positioned so that a distance between the first LED chip of the fourth LED and the second LED chip of the third LED of the first LED group is shorter than a distance between the first LED chip of the fourth LED and the second LED chip of the third LED of the second LED group located adjacent to the first LED group in the row-wise direction.

5. The lighting device according to claim 4, wherein the first LED, the second LED, the third LED, and the fourth LED are arranged in rotation symmetry.

6. The lighting device according to claim 1, wherein the second LED of the first LED group is positioned so that a distance between the first LED chip of the second LED and the second LED chip of the first LED of the first LED group is shorter than a distance between the first LED chip of the second LED and the second LED chip of the first LED of the second LED group located adjacent to the first LED group in the row-wise direction.

7. A display device comprising:
the lighting device according to claim 1; and
a liquid crystal panel that is illuminated by the lighting device.
